(19) United States
(12) Patent Application Publication
(10) Pub. No.: US 2007/0267702 A1
(43) Pub. Date: Nov. 22, 2007

(54) Dynamic threshold P-channel MOSFET for ultra-low voltage ultra-low power applications

(76) Inventors: Walid M. Elgharbawy, Lafayette, LA (US); Magdy A. Bayoumi, Lafayette, LA (US)

Correspondence Address: KEAN, MILLER, HAWTHORNE, D'ARMOND,;MCCOWAN & JARMAN, L.L.P., ONE AMERICAN PLACE, 22ND FLOOR, P.O. BOX 3513, BATON ROUGE, LA, 70821, US

(21) Appl. No.: 11/801,919

(22) Filed: May 11, 2007

Related U.S. Application Data
(60) Provisional application No. 60/800,247, filed on May 12, 2006.

(51) Int. Cl. H01L 29/76

(52) U.S. Cl. 257/365

(57) ABSTRACT

A dynamic threshold voltage p-channel MOSFET (PMOS) for ultra-low power ultra-low voltage applications is disclosed. These applications are of low-to-moderate performance requirements; hence ultra-low voltage subthreshold operation, where the supply voltage is less than the transistors threshold voltage, is suitable. By tying the PMOS body to the output node of the transistor circuit in which this PMOS is part of will provide the necessary body bias for this PMOS threshold voltage to change dynamically with the circuit's output status. The dynamic change of the PMOS transistor threshold voltage will consequently dynamically increase or decrease the subthreshold leakage current which is the switching current in subthreshold circuits.

### BACKGROUND OF THE INVENTION

1. Field of the Invention

This invention relates generally to MOSFET devices and integrated circuits and particularly to MOSFET devices with adaptive body biases for operating- and off-conditions. More particularly, this invention relates to a method of generating the MOSFET device body bias which leads to low threshold operating voltage and high threshold voltages during off-conditions. The devices in the present invention exhibit low currents during off-conditions and high currents during on-conditions which makes them suitable for ultra-low operating voltage ultra-low power operations.

2. Description of the Background Art

The continuing growth of battery-operated devices market has increased the demand for low-energy VLSI design. Battery-operated low-to-moderate performance requirements applications (such as pacemakers, hearing aids, wrist watches, and calculators) have very strong demands on battery lifetime and consequently on power consumption.

The main method of reducing power consumption is through reducing the power supply voltage (V_{DD}) since power consumption is proportional to the square of V_{DD}. Reducing the supply voltage to below three times the threshold voltage of the transistor (3V_{TH}) Will greatly degrade circuits' speed and performance and it is generally avoided in regular MOSFET operation.

A suitable solution to reach the ultra-low power requirements of the said applications is through operating the circuit in the subthreshold region where V_{DD} is lowered to below V_{TH}. The operating current in this case is the subthreshold leakage current (I_{sub}) since under these operating conditions there is no strong inversion channel and the device is operating in the weak inversion region. This subthreshold leakage current is orders of magnitude lower than the strong inversion current which leads to the desired ultra-low power consumption; however, it also leads to a much slower circuit. The subthreshold leakage current in an N-channel MOSFET is expressed as follows:
I_{sub}=μ.(W/L).Cₒₓ.e^{1.8}.Vₜ².exp((V_{GS}−V_{TH})/n.Vₜ).(1−exp(−V_{DS}/Vₜ)).exp(η.V_{DS}/n.Vₜ)
Where μ is the carrier mobility, W is the MOSFET's width, L is its length, Cₒₓ is the gate oxide capacitance, e is the electron charge, V_{GS} and V_{DS} are the gate to source and gate to drain voltages respectively, Vₜ is the thermal voltage, n is a subthreshold slope parameter and it depends on the bulk to source and drain to source voltages, and η is the Drain-Induced Barrier Lowering (DIBL) coefficient.

The N-channel MOSFET's threshold voltage is expressed as follows:
V_{TH}=V_{TH0}+γ.(√(|2Φ_{F}|+V_{SB})−√(|2Φ_{F}|))−η.V_{DS}
Where V_{TH0} is the zero-bias threshold voltage and mainly depends on the manufacturing process; γ is the body effect coefficient (typically equals to 0.4V^{0.5}) and it depends on the gate oxide capacitance, silicon permittivity, doping level, and other parameters; Φ_{F} is the surface potential at threshold (typically |−2Φ_{F}| equals 0.6V); V_{SB} is the source-to-body voltage; and the ηV_{DS} term represents the effect of Drain-Induced Barrier Lowering (DIBL).

Due to their operation in the weak-inversion region, subthreshold CMOS circuits behave differently if compared to the strong inversion CMOS circuits; they become more sensitive to voltage supply variations, temperature variations, and process parameters variations.

One technique well known in the prior art is the dynamic threshold-voltage MOSFET (DTMOS) for MOSFETs fabricated using the Silicon-On-Insulator Complementary Metal Oxide Semiconductor (SOI-CMOS) Technology, which was described in Assaderaghi, F. et al, “Dynamic Threshold-Voltage MOSFET (DTMOS) for Ultra-Low Voltage VLSI,” IEEE Transaction on Electron Devices, volume 44, pages 414-421, 1997. Referring to FIG. 1, DTMOS 100, applied to a N-channel MOSFET (NMOS), and includes a gate 101 tied to an input 102, a drain 103, a source 104, and a body 105.

In the DTMOS technique, the transistor's threshold voltage can be changed dynamically by connecting the gate 101 to the body 105. More particularly, the transistor threshold voltage will change dynamically as input 102 switches between high and low (V_{DD} and ground). When input 102 switches to the high state, transistor's threshold voltage will be lowered as a result of the input being connected to the transistor's body and enabling the transistor to be turned on at a lower input voltage. Consequently, the subthreshold leakage current (switching current) will be dynamically increased and, as a result, more driving current will be supplied to the drain 103 enhancing performance and lowering circuit's delay.

If input 102 goes lower than the transistor's threshold voltage, thus switching off the transistor, the transistor's body 105 will also be low raising the transistor's threshold voltage, lowering the subthreshold leakage current, improving noise immunity, and saving power.

The effective gate capacitance at the gate 101 of a DTMOS is larger than the gate capacitance of a regular MOSFET, but the higher driving current available when input 102 is high diminishes this problem and causes the DTMOS circuit to have less delay than the regular MOS circuits. DTMOS circuits are more robust against temperature and process parameter variations and have better noise immunity as compared to the conventional subthreshold CMOS circuits.

DTMOS technique can be applied to P-channel MOSFET transistors fabricated in Bulk-CMOS technology since NMOS transistors in the said technology require extra fabrication steps to isolate them from neighboring transistors, while PMOS transistors in said technology do not require such extra fabrication steps. P-channel DTMOS technique was introduced by Elgebaly, M. and Sachdev, M. in “A sub-0.5 V dynamic threshold PMOS (DTPMOS) scheme for bulk CMOS technologies,” The 13^{th} International Conference on Microelectronics, pages 75-78, 2001.

FIG. 2 shows a 3-input CMOS OR transistor circuit 200 constructed by connecting the output 214 of a 3-input CMOS NOR transistor circuit 200-1 to the input of a CMOS inverter 200-2.

The 3-input NOR transistor circuit 200-1 consists of three DTPMOS transistors 201, 202, and 203 of the DTPMOS in FIG. 1 connected in series between the supply voltage node V_{DD} and the transistor circuit 200-1's output node 214, and three NMOS transistors 204, 205, and 206 connected in parallel between the output node 214, which is defined as the common connection between the drains of the three NMOS transistors 204, 205, and 206, and the node 216 which is connected to the ground node GND. Source node 216 is defined as the common connection between the sources of the three NMOS transistors 204, 205, and 206 and is connected to the ground node GND.

The DTPMOS transistor 201 has the same input 211 as the NMOS transistor 204 and its source 209 is connected to the supply voltage node V_{DD} and its drain is connected to the internal signal node 210 which is connected to the source of the DTPMOS transistor 202. The DTPMOS transistor 202 has the same input 213 as the NMOS transistor 205 and its source is connected to the internal signal node 210 and its drain is connected to the internal signal node 212 which is connected to the source of the DTPMOS transistor 203. The DTPMOS transistor 203 has the same input 215 as the NMOS transistor 206 and its source is connected to the internal signal node 212 and its drain is connected to the transistor circuit 200-1's output node 214.

The inverter 200-2 consists of a DTPMOS transistor 207 of the DTPMOS in FIG. 1 and an NMOS transistor 208. The DTPMOS transistor 207 has the same input as the NMOS transistor 208 which is the output 214 of the 3-input NOR transistor circuit. The DTPMOS transistor 207's source 217 is connected to the supply voltage node V_{DD} and its drain 218 is connected to the inverter 200-2's output node 220. The NMOS transistor 208 drain is connected to the inverter 200-2's output node 220 and its source 219 is connected to the ground node GND.

### SUMMARY OF THE INVENTION

The principle object of the present invention is to provide a method for controlling a PMOS transistor body dynamically for ultra-low voltage ultra-low power operation. In a preferred embodiment of the invention, the PMOS transistor body bias signal is generated on the circuit level; more specifically the PMOS transistor body is tied to the output node of the transistor circuit which contains the said transistor. In another embodiment of the invention, all PMOS transistors' bodies in a transistor circuit are connected to the transistor circuit's output to provide the necessary body bias for the PMOS transistors. This body bias will increase transistor circuit's speed, reduce transistor circuit's power dissipation, and improve transistor circuit's stability and robustness against different physical and environmental parameters variations compared to the prior art schemes. The present invention has several novel features and advantages when compared to the prior art schemes.

One advantage of the present invention is that it eliminates unnecessary PMOS transistors' bodies switching activity when their corresponding inputs to the PMOS gates switch.

Another advantage of the present invention is that it minimizes or eliminates glitches at the output node.

Another advantage of the present invention is that uses less power than the prior art schemes.

One more advantage of the present invention is that it reduces the load on the input signals at the PMOS transistors' gates leading to faster operation and lower circuit delay.

One further advantage of the present invention is that it reduces the unnecessary high current which was supplied in the prior art schemes even when the transistor circuit's output has made the switching.

These and other objects, advantages, and features of this invention will be apparent from the following description.

### BRIEF DESCRIPTION OF THE DRAWINGS

FIG. 1 illustrates a MOSFET transistor circuit scheme of DTMOS known in the prior art.

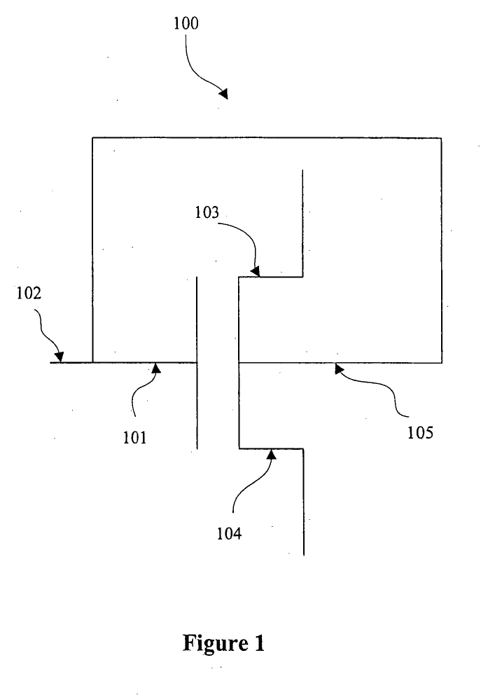

FIG. 2 depicts a 3-input OR transistor circuit schematic using the DTPMOS scheme known in the prior art.

FIG. 3 depicts a 3-input OR transistor circuit schematic using the first preferred embodiment of the present invention.

### DETAILED DESCRIPTION OF THE INVENTION

In the following detailed description of the embodiments reference is made to the accompanying drawings. The drawings are intended to show, by way of illustration, specific embodiments in which the invention may be practiced; like reference numerals in text refer to like elements in drawings. It is to be understood that other embodiments of the invention may be utilized and structural changes may be made without departing from the scope of the present invention.

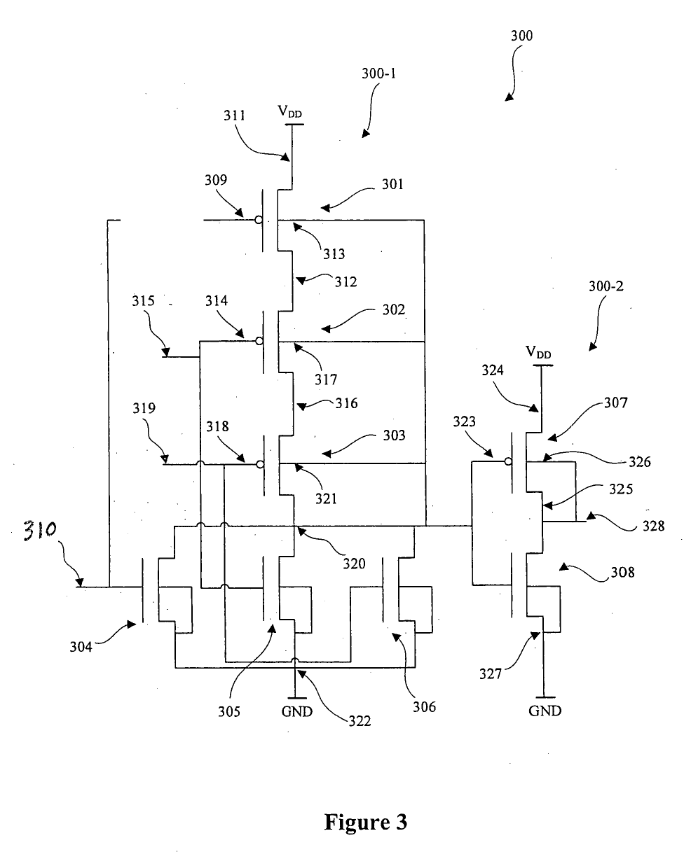

FIG. 3 illustrates the use of the first preferred embodiment of the present invention in constructing a 3-input OR transistor circuit 300. The 3-input OR transistor circuit 300 comprises a 3-input NOR transistor circuit 300-1 and a CMOS inverter 300-2. The output of the 3-input NOR transistor circuit 300-1 is connected to the input of the CMOS inverter 300-2.

The 3-input NOR transistor circuit comprises three PMOS transistors 301, 302, and 303 connected in series between the internal signal nodes 311 and 320, and three NMOS transistors 304, 305, and 306 connected in parallel between the two internal signal nodes 320 and 322. The internal signal node 320 is defined as the common connection between the drains of the three NMOS transistors 304, 305, and 306. Source node 322 is defined as the common connection between the sources of NMOS transistors 304, 305, and 306 and is connected to the ground node GND.

The PMOS transistor 301's gate 309 is connected to the input node 310 which is the same input node connected to the NMOS transistor 304's gate, its source node 311 is connected to the supply voltage node V_{DD}, and its drain is connected to the internal signal node 312 which is connected to the source of the PMOS transistor 302. The PMOS transistor 302's gate 314 is connected to the input node 315 which is the same input node connected to the NMOS transistor 305, its source is connected to the internal signal node 312, and its drain is connected to the internal signal node 316 which is connected to the source of the PMOS transistor 303. The PMOS transistor 303's gate 318 is connected to the input node 319 which is the same input node connected to the NMOS transistor 306, its source is connected to the internal signal node 316, and its drain is connected to the transistor circuit 300-1's output node 320.

The CMOS inverter 300-2 consists of a PMOS transistor 307 and an NMOS transistor 208. The PMOS transistor 307's gate 323 is connected to the inverter 300-2's input 320, which is the 3-input NOR 300-1 output. PMOS transistor 307 has the same input node 320 which is connected to the NMOS transistor 208 gate. The PMOS transistor 307's source 324 is connected to the supply voltage node V_{DD} and its drain 325 is connected to the inverter 300-2's output node 328. The NMOS transistor 308 drain is connected to the inverter 300-2's output node 328 and its source 327 is connected to the ground node GND.

In the first preferred embodiment of this invention and in reference to the illustration example shown in FIG. 3, the bodies nodes 313, 317, and 321 of the three PMOS transistors 301, 302, and 303 respectively in the 3-input NOR transistor circuit 300-1, are connected to the output node 320 of the circuit 300-1 to provide the necessary dynamic change in the threshold voltage of transistors 301, 302, and 303 to ensure correct operation of the circuit as will be described in details hereafter. Likewise, the body node 326 of the PMOS transistor 307 in the CMOS inverter 300-2 is connected to the output node 328 of the circuit 300-2.

In one embodiment of the present invention, the three PMOS transistors 301, 302, and 303 should share the same n-well during the Bulk-CMOS fabrication process in order to have the same body bias signal from the internal signal node 320. The PMOS transistor 307 will have its own n-well in isolation from the other PMOS transistors in this specific circuit since it is tied to the inverter 300-2's output node 328 and it is different than the body bias signal supplied to other PMOS inverter in this transistor circuit example. It is to be understood that the feature related to this embodiment should be applied to all PMOS transistors sharing the same body bias signal in any circuit other than the one described in this text and in FIG. 3.

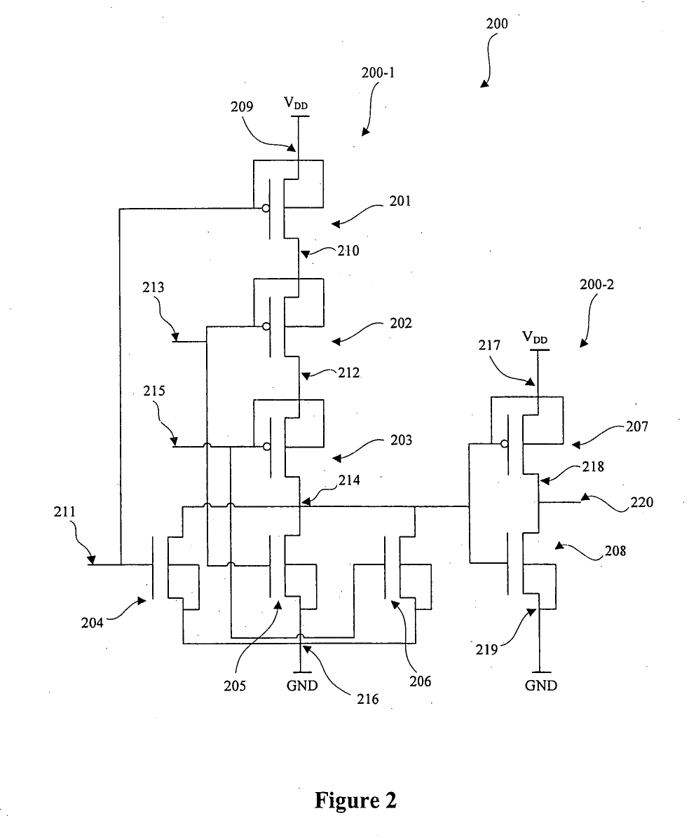

In the prior art and in reference to FIG. 2, DTPMOS transistors 201, 202, 203, and 207 bodies are biased individually by connecting these bodies to their respective inputs 211, 213, 215, and 214; respectively, so that each transistor may have a high or low threshold voltage depending on its input state, hence low or high subthreshold leakage current, independent of the transistor circuit, in which these transistor are part of, state. Consequently, a transistor circuit may experience a high current even though it may not be needed due to individual PMOS transistors states and to the circuit output(s) state(s) (output nodes 214 and 220 in FIG. 2). Moreover, such high currents introduce glitches in the output signals 214 and 220 waveforms which further increase circuit's power consumption.

In the present invention and in reference to FIG. 3, the bodies of all PMOS transistors are connected to their corresponding transistor circuit output. In the first preferred embodiment of the present invention a body biasing signal is generated on the transistor circuit level by the circuit output itself so that the used biasing signal will not vary from a transistor to a transistor within the same circuit as in the prior art, thus the subthreshold leakage current (the operating current) will change dynamically according only to the circuit output state and not to individual transistors operating states.

The operation of the present invention is different than that of the prior art and it will be described in details hereafter with reference to FIG. 3. Throughout the following detailed description of the present invention the term “PMOS network” will refer to the PMOS transistor(s), PMOS transistor configuration, and PMOS transistors connection in a transistor circuit. For example, in FIG. 3 there is a PMOS network comprising PMOS transistors 301, 302, and 303 in circuit 300-1 and there is another PMOS network comprising only PMOS transistor 307 in circuit 300-2.

In reference to FIG. 3, when the PMOS network comprising transistors 301, 302, and 303 is off (in the case of any of the inputs are high in the FIG. 3), the circuit 300-1 output node 320 will be low and since this output node is connected to the said PMOS transistors bodies then the PMOS transistors bodies' bias will be low giving some rise to the subthreshold leakage current to some intermediate value. This variation in body bias will lead to a decrease in the PMOS transistors threshold voltage and hence an increase in the subthreshold leakage current, which is the switching current in the subthreshold circuits to which the present invention is related. However, this intermediate subthreshold leakage current value is less than the current value experienced by the circuit in the prior art scheme. In the prior art scheme, FIG. 2, and when the PMOS transistors inputs are low (PMOS transistors are on and PMOS network is on) the subthreshold leakage current is increased exponentially due to the dual effect of lower body bias, hence lower threshold voltage) and increase in the gate-to-source voltage (V_{GS}); in the present invention the increase in the subthreshold leakage current when the PMOS network is off is due only to the effect of lower body bias and V_{GS} still has no effect since the transistors are off. Therefore, the said intermediate subthreshold current value is less than the high current value in the prior art when the PMOS network is on.

In the present invention and in reference to FIG. 3, as soon as the PMOS network of circuit 300-1 switches on (inputs 310, 315, and 319 are low and all PMOS transistors 301, 302, and 303 are on simultaneously), the said PMOS transistors bodies are already biased low from the previous state when the PMOS network was off and instantaneous high subthreshold leakage current will flow in the PMOS network leading the output node 320 to charge causing circuit 300-1 to switch faster and the output to rise faster than the prior art scheme (FIG. 2). When the transistor circuit 300-1 output node 320 rises to logic high (V_{DD}), the PMOS transistors 301, 302, and 303 bodies will be forced to rise to V_{DD} and this, consequently, will suppress the subthreshold leakage current afterwards, since it will lead to higher PMOS transistors threshold voltage; however, this will happen only after this extra current is not needed anymore and the circuit 300-1 output node 320 has already evaluated correctly.

In the prior art (FIG. 2), and when the PMOS network switches on, PMOS transistors 201, 202, and 203 bodies need some time to discharge after being charged in the previous state when the PMOS network was off which causes the prior art circuit to be slower than the present invention. After the prior art circuit 200-1 (FIG. 2) has finished switching and its output node 214 has risen to V_{DD}, still a high subthreshold leakage current will continue to flow, since the PMOS transistors bodies are still connect to the transistors inputs which are still low, causing the circuit to dissipate more power than necessary as long as the PMOS transistors are on. Also, high drain currents in the prior art scheme come at the expense of much larger currents drawn from the input sources which add to the circuit total power dissipation.

Similar discussions and illustrations relating to the present invention can be demonstrated on the inverter circuit 300-2 in FIG. 3 and in comparison to the inverter circuit 200-1 in FIG. 2 of the prior art.

In the prior art scheme and in reference to FIG. 2, all PMOS transistors bodies are tied to their corresponding inputs, this will cause the output node 214 to experience signal glitches when any of the PMOS transistors inputs make a switching regardless of the circuit output state. This leads the prior art scheme to experience more power dissipation, more noise generation within the circuit, and lower reliability. The present invention minimizes or completely eliminates such glitches because the PMOS transistors bodies, and hence the circuit's subthreshold leakage current, are not a function of the applied input signals, instead they depend only on the circuit's output state.

Due to the fact that the present invention circuits have some intermediate current value during the time in which the PMOS network is off, the present invention will work best if the circuit has a moderate-to-high switching activity. This way it will continuously save more power than the prior art scheme while if it had a low activity factor then it would still outperform the prior art scheme in terms of speed and power consumption, but it will suffer from some high currents and hence its power consumption will increase during circuit idle durations causing gained savings to be reduced.

There are of course other alternate embodiments that are obvious from the foregoing descriptions and illustrations of the invention, which are intended to be included within the scope of the invention, as defined by the following claims.

We claim:

1. A semiconductor MOSFET device with a channel of the first conductivity type material having a body bias that changes dynamically comprising:
a substrate of the first semiconductor material;
a well of the second conductivity type comprising the MOSFET device body and is formed in the said substrate;
diffusion source and drain regions of the first conductivity type are formed in said well;
the said source and drain regions are separated by a channel region therebetween formed within said well; and
a gate electrode formed on a dielectric layer.

2. The device of claim 1 wherein the first semiconductor material is silicon.

3. The device in claim 1 wherein the first conductivity type is p-type.

4. The device in claim 1 wherein the second conductivity type is n-type.

5. A circuit comprising:
a connection to the supply voltage source;
a connection to the ground;
a plurality of MOSFET devices of claim 1; and
a plurality of MOSFET devices with channels of the second conductivity type material fabricated on the said substrate of claim 1, which comprises the body of the said MOSFET devices, comprising diffusion source and drain regions of the second conductivity type, a channel region separating the said source and drain regions, and a gate electrode formed on a dielectric layer.

6. The circuit of claim 5 wherein the said circuit represents a logic gate generating an output signal through an output node from within the said circuit.

7. The circuit of claim 5 wherein the said supply voltage source has a voltage source value less than the threshold voltage of the MOSFET devices of claim 1 hence the said circuit will operate in the subthreshold region of operation.

8. The circuit of claim 5 wherein the sources and drains of the said MOSFET devices with the first conductivity type material channels are connected together in a parallel fashion, in a serial fashion, or in a combination of both between the said connection to the supply voltage source and the output node of claim 6.

9. The circuit of claim 5 wherein the sources and drains of the said MOSFET devices with the second conductivity type material channels are connected together in a parallel fashion, in a serial fashion, or in a combination of both between the output node of claim 6 and the said connection to the ground of claim 5.

10. The output signal of claim 6 is tied to the bodies of the MOSFET devices with the first conductivity type material channels of claim 5; the said output signal generates the necessary body bias for the said MOSFET devices to change the said MOSFET devices threshold voltage dynamically.
